(19) United States
(12) Patent Application Publication
(10) Pub. No.: US 2021/0289666 A1
(43) Pub. Date: Sep. 16, 2021

(54) HEAT SINK STRUCTURE

(71) Applicants: Agile Power Switch 3D - Integration aPSI3D, Tarbes (FR); IRT Antoine de Saint Exupery, Toulouse Cedex 4 (FR); Institut Catholique d'Arts et Metiers, Toulouse (FR)

(72) Inventors: Jacques Pierre Henri FAVRE, Toulouse (FR); Jean-Michel Francis REYNES, Gaillac (FR); Jean-Pierre Bernard Marie FRADIN, Bruguieres (FR); Claudia CADILE, Cugnaux (FR); Renaud André LACABANNE, Tarbes (FR)

(21) Appl. No.: 16/618,276

(22) PCT Filed: May 31, 2017
(86) PCT No.: PCT/IB2017/000837

§ 371 Date: Nov. 29, 2019

(51) Int. Cl. H05K 7/20; F28F 3/02; F28F 3/06

(52) U.S. Cl. CPC H05K 7/20418; H05K 7/20336; F28F 2215/00; F28F 3/06; F28F 3/022

(57) ABSTRACT

Some embodiments are directed to a kit of parts that includes heat sink parts, each heat sink part having a contact area for contacting a surface of an electronic device. The heat sink parts are connected but are spaced apart to allow them to adjust and keep their contact areas contacting the surface of the electronic device when the surface is distorted, for example due to heating. A heat sink part includes at least two spaced apart heat sink elements which are connected.

### CROSS REFERENCE TO RELATED APPLICATION

This application is a national phase filing under 35 C.F.R. § 371 of and claims priority to PCT Patent Application No. PCT/IB2017/000837, filed on May 31, 2017, the contents of which are hereby incorporated in its entirety by reference.

### BACKGROUND

Some embodiments relate to a heat sink structure. More in particular, some embodiments relate to a heat sink structure including heat sink parts, such as fins or ribs.

Heat sinks are known, in particular in the field of electronics. Electronic components, such as processors and power switches, produce heat when in use. Such components may not radiate enough heat to keep their temperature within a normal working range. For this reason, a heat sink may be mounted on the component. A heat sink may be a metal structure having elements which serve to lead the heat away from the component.

U.S. Pat. No. 4.884,331, for example, discloses a unitary heat sink apparatus for removal of heat from a heat generating component, such as a semiconductor device. The heat sink apparatus has a heat sink body or base portion from which parallel fins extend outwardly, the fins being separated by grooves produced by sawing.

U.S. Pat. No. 6,807,059 discloses a pin fin heat sink manufactured by fusion or stud welding of fins to a base. The base is shown to be constituted by a single large plate supporting a large number of pin fins, in one embodiment 256 pin fins.

Such related art arrangements are useful when the electronic component on which they are to be mounted have a sufficiently flat top surface which allows a good thermal contact with the heat sink. However, in practice the top surfaces of electronic components are often not perfectly flat, which results in a less than perfect heat transfer. In addition, the top surface of the electronic component may become distorted as the component heats up, thus reducing the heat transfer even when the initial heat transfer was good.

### SUMMARY

It is an aspect of the presently disclosed subject matter to solve this problem by providing a heat sink structure including a plurality of heat sink parts, each heat sink part having a contact area for contacting a surface of an electronic device, the heat sink parts being spaced apart so as to allow them to adjust and keep the contact areas contacting the surface of the electronic device when the surface is distorted.

By providing a plurality of heat sink parts which are spaced apart, the heat sink structure is better suited to adjust to the surface of the electronic device. In particular, as the heat sink parts are spaced apart, they are capable of altering their mutual positions so as to adjust the heat sink structure to the electronic component. When the surface of the electronic component is distorted due to heat generation and/or other causes, this adjustment of the heat sink structure allows the contact areas of the heat sink parts to remain in contact with the surface of the electronic component.

The heat sink structure of the presently disclosed subject matter therefore includes multiple spaced apart contact areas. Being spaced apart, for example being separated by gaps, allows those contact areas to absorb changes in the surface of the electronic component. In the related art, however, a heat sink structure has a single, relatively large contact area, typically the bottom surface of a base plate, which is not capable of absorbing changes in the surface of the electronic component. By providing spaced apart heat sink parts, and hence spaced apart contact areas, a more flexible heat sink structure is obtained.

The contact area of a heat sink element of the presently disclosed subject matter may be located at an side or end of the heat sink part, and may be equal to a side surface or end surface of the heat sink part.

A heat sink part may be constituted by a single component, such as a heat sink rib. In some embodiments, however, a heat sink part may be constituted by multiple components which may or may not be connected. In an embodiment, therefore, a heat sink part may include at least two heat sink elements, which may be connected by a connecting member.

In an embodiment, the heat sink elements are not connected. That is, there may be no direct connection between the heat sink elements of the heat sink structure, the heat sink elements only being mechanically connected through the electronic component on which they are mounted. However, in other embodiments at least two heat sink elements are connected by a connecting member. Such a connecting member may connect two or more heat sink elements and may thus form a heat sink part. A linear connecting member may, for example, connect a row of heat sink elements. A connecting member may be integral with the two or more heat sink elements it connects, thus forming a single component, but a connecting member may also be constituted by a separate element which is attached to the heat sink elements.

A heat sink part may therefore be constituted by a single rib-like component, or by a number of heat sink elements which may or may not be connected, or by a combination of one or more rib-like elements and heat sink elements which may or may not be connected.

In an embodiment, the connecting member constitutes the contact area for the heat sink part. That is, the connecting member (or connecting members) may be located at the ends of the heat sink elements and may have a surface which serves as contact area for the heat sink elements it connects. In such an embodiment, the connecting member may be integral with the heat sink elements it connects, and may thus form a combe-shaped structure, for example. Two connecting members may be spaced apart by gaps which constitute through grooves in the heat sink structure, thus spacing the heat sink parts apart.

The contact areas of the heat sink parts may define a common plane, that is, a plane which is common to those contact areas, the contact areas substantially lying in the common plane. When at least one connecting member constitutes the contact areas for at least two heat sink elements, then the connecting member may include a surface in the common plane. In other embodiments, however, the at least one connecting member may be spaced apart from the common plane. That is, the connecting member may not be located at the end of the heat sink elements where the contact areas are located, but for example at the opposite end of the heat sink element, or near their middle section.

In embodiments in which the at least one connecting member is not located at the end of the heat sink elements where the contact areas are located, but for example at the opposite end of the heat sink elements, the heat sink elements effectively extend from the contact areas to the at least one connecting member but may not extend beyond the at least one connecting member. Thus, the at least one connecting member may be located at the end of the heat sink elements which is the furthest away from the contact areas.

A connecting member may be coupled with two or more heat sink elements without being coupled to other parts of the heat sink structure. In some embodiments, however, at least two connecting members may be coupled, and may constitute an integral structure. In such embodiments, the connecting members may be coupled to form a base of the heat sink structure.

In accordance with the presently disclosed subject matter, the heat sink parts are spaced apart. To this end, two adjacent connecting members may be spaced apart, at least over part of their lengths, to provide the flexibility that may be required for adjusting to distorted or irregular surfaces. In some embodiments, connecting members may be joined at their ends, leaving a gap over the remainder of their length.

Although the heat sink elements may be solid, in some embodiments at least one heat sink element is hollow. A hollow heat sink element has a reduced weight and an increased surface area, and may therefore be advantageous.

At least one heat sink elements may be a pin heat sink element, that is, a heat sink element shaped like a pin. At least one heat sink part may be rib-shaped. A heat sink part may be hollow, solid or partially hollow.

At least one heat sink part may have an undulating shape. Such a shape increases the surface area of the heat sink part, thus improving the heat sinking capabilities of the structure.

In embodiments of the presently disclosed subject matter, the heat sink parts may extend substantially in parallel, and possibly substantially perpendicular to a common plane. In some embodiments, however, the heat sink parts may not be parallel and may, for example, each have a different angle with respect to a common plane. In such embodiments, the heat sink parts and/or heat sink elements may diverge in the direction from the contact areas.

The heat sink structure of the presently disclosed subject matter may further include a base or base plate arranged at the ends of the heat sink elements opposite to the ends including the contact areas. That is, the base may be arranged on the end of the heat sink elements which are furthest away from the contact areas and therefore from the surface of the electronic device. This base plate can therefore be said to be placed on top of the heat sink structure.

The base plate may be arranged to serve as a reservoir for receiving a solid-liquid or solid-solid PCM (Phase Change Material). PCMs are typically diphasic materials. Suitable PCMs are, for example, paraffin, salt hydrates, or other materials which will be chosen according to the value of the corresponding phase change temperature. The purpose of the reservoir is to use latent energy storage to decrease the maximum temperature value during a transient mission profile.

The presently disclosed subject matter further provides an electronic device, provided with a heat sink structure as described above. The electronic device, which may include a power switch, may be provided with a surface, such as a top surface, for mounting a heat sink structure. The electronic device may further include a housing and electrical contacts extending from the housing.

In the above, the heat sink structure was referred to as being mounted, or capable of being mounted, on an electronic component, such as a power switch. In some embodiments, the electronic component may be mounted on the heat sink structure, or the heat sink structure may be arranged for mounting an electronic component. In some embodiments, the component may not be an electronic component but an optical component, for example, or an electro-optical component.

### BRIEF DESCRIPTION OF THE FIGURES

The presently disclosed subject matter will further be explained with reference to exemplary embodiments illustrated in the drawings, in which:

FIG. 1 schematically shows an embodiment of a heat sink structure according to the presently disclosed subject matter.

FIG. 2 schematically shows another embodiment of a heat sink structure according to the presently disclosed subject matter.

FIG. 3 schematically shows another embodiment of a heat sink structure according to the presently disclosed subject matter.

FIG. 4 schematically shows a fourth embodiment of a heat sink structure according to the presently disclosed subject matter.

FIG. 5 schematically shows another embodiment of a heat sink structure according to the presently disclosed subject matter.

FIG. 6 schematically shows another embodiment of a heat sink structure according to the presently disclosed subject matter.

FIG. 7 schematically shows another embodiment of a heat sink structure according to the presently disclosed subject matter.

FIG. 8 schematically shows another embodiment of a heat sink structure according to the presently disclosed subject matter.

FIG. 9 schematically shows another embodiment of a heat sink structure according to the presently disclosed subject matter.

FIG. 10 schematically shows another embodiment of a heat sink structure according to the presently disclosed subject matter.

FIG. 11 schematically shows another embodiment of a heat sink structure according to the presently disclosed subject matter.

FIG. 12 schematically shows another embodiment of a heat sink structure according to the presently disclosed subject matter.

FIG. 13 schematically shows an embodiment of an electronic device provided with heat sink structures according to the presently disclosed subject matter.

FIG. 14 schematically shows another embodiment of an electronic device provided with heat sink structures according to the presently disclosed subject matter.

### DETAILED DESCRIPTION OF EXEMPLARY EMBODIMENTS

The presently disclosed subject matter provides a heat sink structure which includes a number of heat sink parts. Each heat sink part may have a contact area for contacting a surface of an electronic device, such as an electronic switch or amplifier. The heat sink parts may be spaced apart. This may allow the heat sink parts to adjust their mutual positions so as to keep their contact areas contacting the surface of the electronic device when this surface is distorted, for example due to heat development.

The heat sink parts of the presently disclosed subject matter may have various shapes and sizes. In some embodiments, a heat sink part may include a number of heat sink elements, such as pins. A row of pins may be connected by a connecting member, thus forming a longitudinal heat sink part. In some embodiments, such a longitudinal heat sink part may be constituted by a plate or rib instead of a connected row of pins. In some embodiments, the plate may be undulating. Longitudinal heat sink parts may be connected to each other, for example at their ends. However, the heat sink parts may still be separated by gaps, which allows the heat sink parts a degree of relative movement to adjust to distortions of a surface on which the heat sink structure may be mounted.

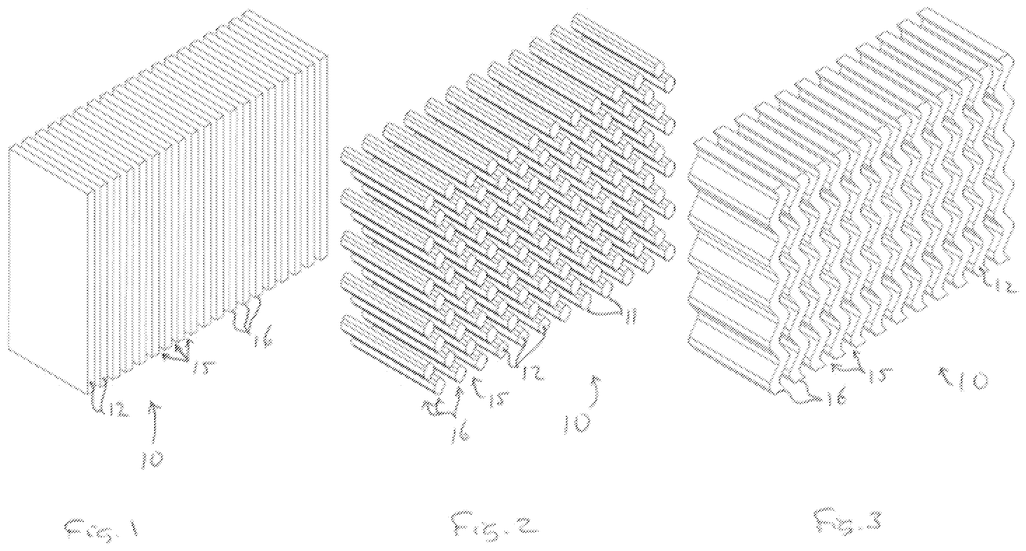

In the embodiment of FIG. 1, the heat sink structure 10 is shown to includes a series of heat sink parts 16 separated by gaps 15. In this embodiment, the heat sink parts 16 are constituted by plates which are not connected to each other. The spacings or gaps 15 allow a relative movement of the plates, in particular in a direction perpendicular to their contact surfaces 12. As shown in FIG. 1, the contact surfaces 12 are in this embodiment constituted by the sides of the plate-shaped heat sink parts 16, in particular the longer sides of the rectangular plates. It will be understood that in other embodiments, the shorter sides of rectangular plates may be used as contact surfaces for contacting the electronic device. In yet other embodiments, the substantially flat heat sink parts may be square.

The contact surfaces 12 may lie approximately in a common plane, at least initially. It will be understood that the surface on which the heat sink structure 10 is mounted, or at least the surface which the heat sink structure 10 abuts, may or may not initially be flat, and may distort as the surface heats up. That is, an initially flat surface may become curved or may deviate from a flat surface in another manner, for example by showing undulations, local depressions or local protrusions. Embodiments can be envisaged in which the surface of the electronic device is initially not flat but curved, for example.

In the embodiment of FIG. 1, the heat sink parts 16 are not connected to each other. They may be held in place by being mounted on the electronic device (not shown in FIG. 1), for example by gluing. Alternatively, or additionally, their positions may be determined by support members (not shown), for example comb-shaped support members of which the teeth are located between the plates. It will be understood that the spacings or gaps 15 between the heat sink parts 16 not only allow relatively movement of the heat sink parts, but also allow air to be passed between the heat sink parts.

In the embodiment of FIG. 2, the heat sink parts 16 are not constituted by plates but by rows of heat sink elements 11. In this embodiment, the heat sink elements 11 are round and elongate elements which may also be referred to as pins. Each heat sink element 11 has a contact surface 12, which in this embodiment is approximately circular.

The embodiment of FIG. 2 offers the advantage of allowing more relatively movement, as the heat sink parts 16 are each made up of separate heat sink element 11. Thus not only the heat sink parts 16 (here: the rows of pins) but also the heat sink elements 11 (here: the pins) may move slightly as the surface of the electronic device changes shape. It will be understood that this relative movement will be primarily in the longitudinal direction of the pins, although some lateral movement of the pins may also be possible. Although the pins or heat sink elements 11 are shown to be parallel, their angles relative to the surface of the electronic device need not be all the same and may in some embodiments change during use.

As in the embodiment of FIG. 1, the heat sink elements 11 are not connected to each other. They may be held in place by being mounted on the electronic device (not shown in FIG. 2), for example by gluing. Alternatively, or additionally, their positions may be determined by suitable support members (not shown), for example a plate having circular holes for accepting the pins. Such a plate may be made of metal of plastic, for example.

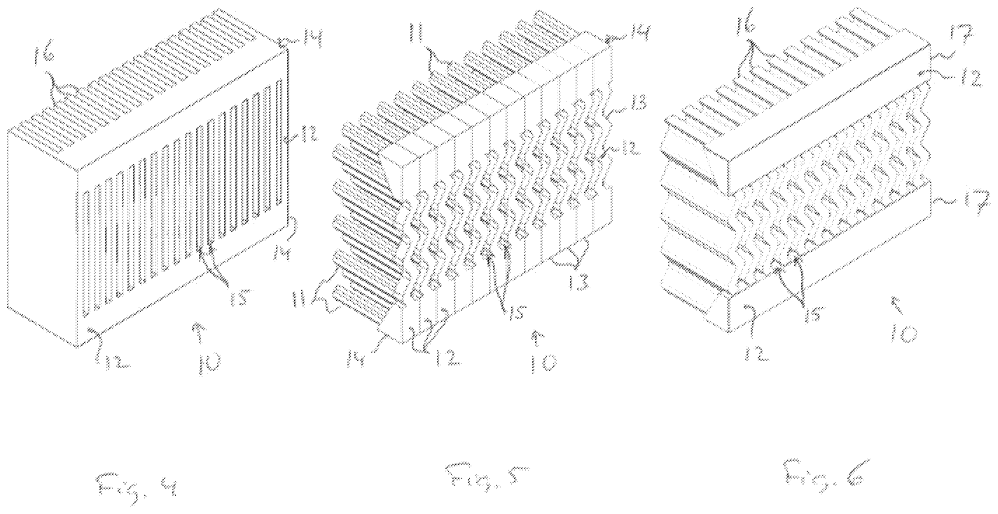

The embodiment of FIG. 3 is similar to the embodiment of FIG. 1 with the exception of the shape of the plate-like heat sink parts 16. While the heat sink parts 16 in the embodiment of FIG. 1 are substantially straight, the heat sink parts 16 in the embodiment of FIG. 3 are undulating: the plates have a wave-like surface. As a result, the contact surfaces 12 are have a meandering or winding shape. The undulating shape of the heat sink parts 16 increases their surface are and thereby improves their heat sinking capabilities.

In the embodiments of FIG. 3 the heat sink parts 16 are also not connected directly to each other, as in the embodiments of FIG. 1 and 2.

In the embodiment of FIG. 4, the heat sink parts 16 are essentially identical to the heat sink parts 16 of FIG. 1 and are also constituted by plates. The plates are joined at their end sections 14 (seen in the longitudinal direction of the plates) to form a single, integrated heat sink structure 10. In according with the presently disclosed subject matter, the plates or heat sink parts 16 are separated by gaps 15 which space the heat sink parts 16 apart. In the embodiment shown in FIG. 4, the gaps 15 extend over a substantial part of the length of the plate-shaped heat sink parts 16, that is, over approximately 70% of their length. To achieve the desired flexibility of the heat sink structure, the gaps should extend over at least 60% of the length of the heat sink parts, and possibly over at least 70%. In some embodiments, the gaps 15 may extend over between 80% and 95% of the length of the plates. In the embodiment of FIG. 1 the plates are not connected at their ends, thus achieving 100%. In the embodiment of FIG. 4, the contact areas 12 of the heat sink parts 16 are constituted by the sides of the plates, as well as by the connecting areas at the end sections 14. In this embodiment, the sides are integral with the areas of the end sections where the plates are connected to each other.

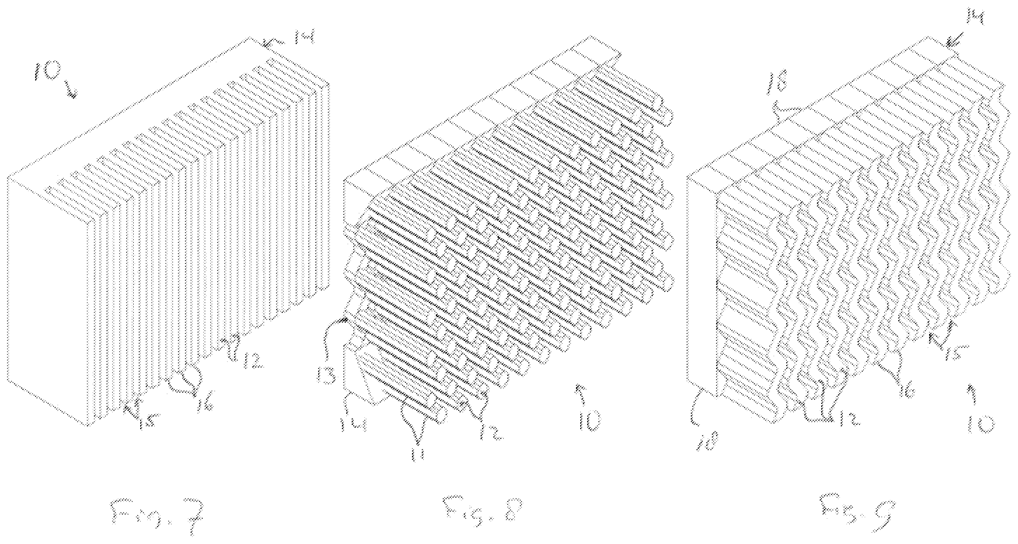

The embodiment of FIG. 5 differs from the embodiment of FIG. 4 in that the heat sink parts 16 are constituted by rows of pin-shaped heat sink elements 11, as in the embodiment of FIG. 2. In the embodiment shown in FIG. 5, five pin-shaped heat sink elements 11 are connected by a connecting member 13, thus proving the heat sink parts 16 which are arranged in parallel and are separated by gaps 15. Each connecting member 13 has a side surface which constitutes the contact area 12 of the heat sink part 16. At their end sections 14, the connecting members 13 are wider. This allows the connecting members 13 to contact each other at their end sections 14 while leaving the gaps or spacings 15 between the major part of their lengths. The connection members 13 may only touch each other at their end sections 14, thus allows relative movement of the heat sink parts. Alternatively, the end sections 14 of the connecting members 13 may be connected to each other, for example by gluing, thus forming a single heat sink structure 10.

In the embodiment of FIG. 5, the pins or heat sink elements 11 can be said to have an indirect thermal connection with the contact areas 12, through the connecting members 13. It is recalled that in the embodiment of FIG. 1 the heat sink elements 11 have a direct thermal connection with their contact areas, as in that embodiment the contact areas are the end surfaces of the pins, and the connecting members 13 are absent.

A further embodiment is schematically illustrated in FIG. 6, where the heat sink parts 16 are constituted by undulating plates, as in the embodiment of FIG. 3. It will be understood that in this embodiment, as in the embodiment of FIG. 4, no distinct connecting members 13 are present. The undulating plate-like heat sink parts 16 of FIG. 6 are shown to be connected at their end sections 14 by transverse members 17 but are for more than 50% of their length separated by gaps 15. As in the other embodiments, these spacings or gaps 15 allow some degree of adjustment of the heat sink parts 16 relative to each other, such that the contact areas 12 can remain in contact with the surface of an electronic component, even when that surface distorts in use. Surfaces of the transverse members 17 constitute the contact surfaces 12 in this embodiment.

The embodiment of FIG. 7 is similar to the one of FIG. 4 but is reversed: the contact areas 12 are located on the sides of the heat sink parts 16 which are furthest away from the end sections 14. Compared to the embodiment of FIG. 4, this embodiment may provide a better adaptation to a distortion of the surface of the electronic device, as the gaps or spacings 15 extend over the full length of the heat sink parts 16. Still, this heat sink structure 10 is an integral structure.

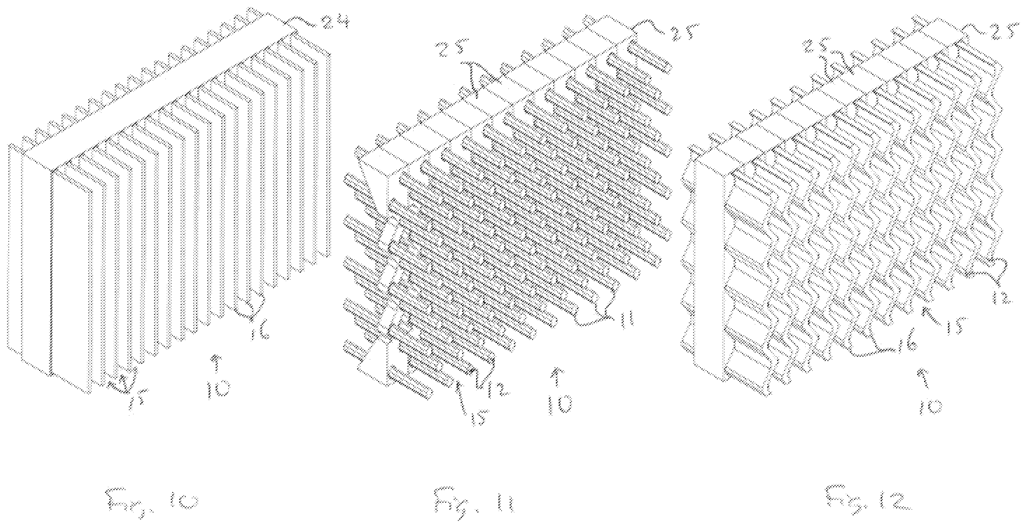

The embodiment of FIG. 8 is similar to the one of FIG. 5 but is also reversed: the contact areas 12 are located on the sides of the heat sink elements 11 which are furthest away from the connecting members 13 and the end sections 14. Compared to the embodiment of FIG. 5, this embodiment may provide a better adaptation to a distortion of the surface of the electronic device.

The embodiment of FIG. 9 is similar to a reversed version of the one of FIG. 5: the contact areas 12 are located on the sides of the heat sink parts 16 which are furthest away from the end sections 14. Compared to the embodiment of FIG. 6, this embodiment may provide a better adaptation to a distortion of the surface of the electronic device. In contrast to the embodiment of FIG. 6, this embodiment includes base members 18 which are similar to the connection members 13 of FIG. 5 but have a uniform width. The parallel base members 18 may or may not be connected to each other.

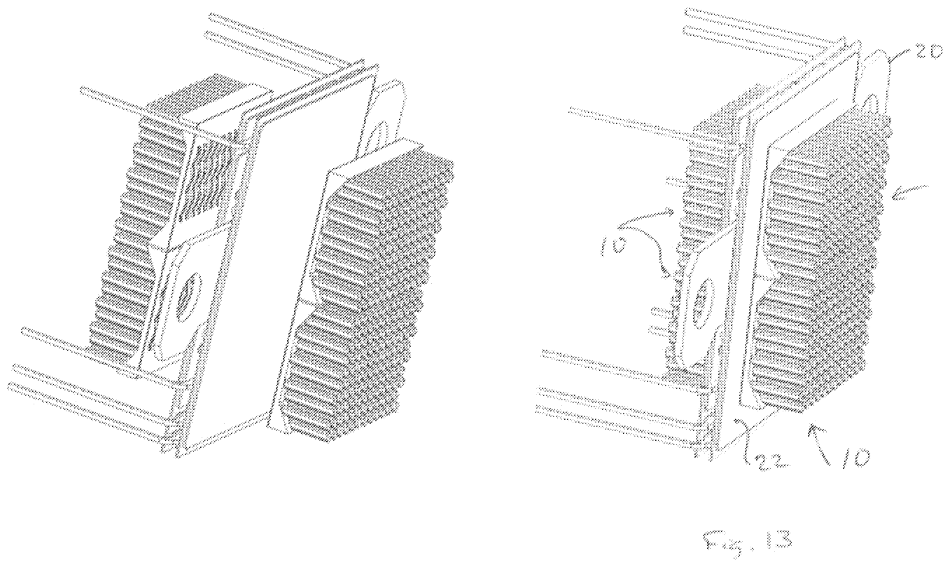

The embodiment of FIG. 10 is substantially identical to the embodiment of FIG. 1, with the exception of the added guide structure 24 which serves to position the heat sink parts 16. This guide structure 24 may have suitable slots for accepting the heat sink parts 16, and may be made of metal or plastic. The guide structure 24 may be removed once the heat sink structure 10 is mounted on the electronic device. In some embodiments, the guide structure 24 may remain in place during use of the heat sink structure 10.

Similarly, the embodiment of FIG. 11 is substantially identical to the one of FIG. 2, with the exception of the added guide members 25, which together constitute a guide structure. The guide members 25 of this embodiment are shown to have round openings in which the heat sink elements 11 may slidingly fit so as to position the heat sink elements on the surface of the electronic device. After positioning, the guide members 25 may be removed, although in some embodiments they may remain in place. The guide members 25 may be separate components or may be connected (for example by gluing) to form a single guide structure.

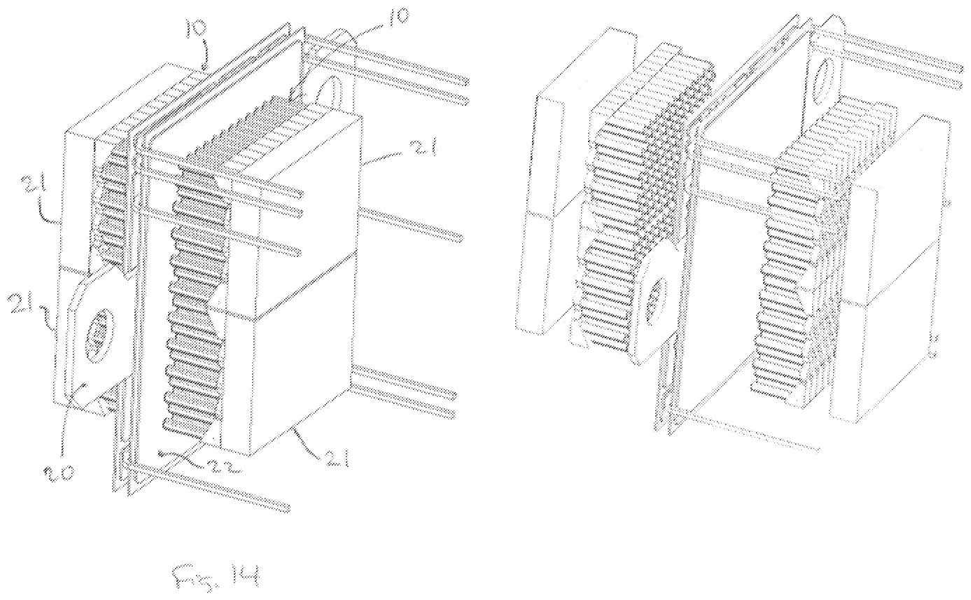

The embodiment of FIG. 12 is essentially identical to the embodiment of FIG. 3, with the exception of the addition of guide members 25. The guide members of FIG. 12 have suitable openings for accepting the heat sink parts 16 having a meandering shape. The guide members 25 may be separate members or may be joined to form a single guide structure, and may or may not be removed after mounting the heat sink structure on the electronic device.

It is noted that the contact areas 12 shown in FIGS. 1 to 12 are substantially flat. However, this is not essential and embodiments can be envisaged in which the contact areas 12 are curved, for example, to accommodate a curved surface of an electronic device. Still, the gaps between the heat sink elements or heat sink parts allow some relative movement and therefore some adjustment to changes in the surface of the electronic device. In this way, a distortion of the surface of the electronic component will not degrade the thermal contact between the electronic component and the heat sink structure.

In some embodiments, at least some heat sink elements and/or heat sink parts may be hollow. Thus, hollow pins and/or hollow plates may be used. In some embodiments, at least some heat sink elements may be solid. That is, solid pins and/or solid plates may be used.

FIG. 13 schematically shows an electronic device provided with heat sink structures according to the presently disclosed subject matter. The electronic device 20 (of which only electrical terminals may be clearly visible) is accommodated between four heat sink structures 10, two on each side. The electronic device 20 is provided with surfaces 22 on which the heat sink structures 10 are mounted. The electronic device 20 may be an electronic power switch, for example.

FIG. 14 also shows an electronic device 20 provided with heat sink structures 10 according to the presently disclosed subject matter. The heat sink structures 10 are mounted on surfaces 22 of the electronic device 20. In this embodiment, PCM (Phase Change Material) reservoirs 21 are mounted on the heat sink structures 10. In some embodiments, the heat sink structure may have a base which may serve as a PCM reservoir for receiving PCM material (or, more in general, diphasic material).

Accordingly, an electronic device may be provided with a heat sink structure according to the presently disclosed subject matter. The electronic device may, for example, be a power switch, but may also be an amplifier, rectifier or other electronic device.

It will be understood that the description of the presently disclosed subject matter given above is not intended to limit the presently disclosed subject matter in any way. Singular nouns and the articles “a” and “an” are of course not meant to exclude the possibility of plurals. Devices mentioned in this document may be replaced with their successors, even if these successors are not yet known at the time of writing. The abstract should never be used to limit the scope of the claims, and neither should reference numbers in the claims.

It will further be understood by those skilled in the art that the presently disclosed subject matter is not limited to the embodiments mentioned above and that many additions and modifications are possible without departing from the scope of the presently disclosed subject matter as defined in the appending claims.

1. A kit of parts comprising:
a heat sink assembly including a plurality of heat sink parts, each of the heat sink parts having a contact area for contacting a surface of an electronic device, the heat sink parts being spaced apart and not directly connected to each other, and
a guide structure to position the heat sink parts relative to the surface of the electronic device, the guide structure comprising respective openings for accepting and providing a sliding fit for the respective heat sink parts to enable positioning the heat sink parts on the surface of the electronic device.

2. The kit of parts according to claim 1, wherein each of the heat sink parts includes at least two heat sink elements.

3. The kit of parts according to claim 2, wherein the at least two heat sink elements are connected by a connecting member.

4. The kit of parts according to claim 3, wherein the connecting member serves as the contact area for the heat sink part.

5. The kit of parts according to claim 3, wherein at least two connecting members are coupled to form a base.

6. The kit of parts according to claim 5, wherein the at least two connecting members are coupled at end sections thereof.

7. The kit of parts according to claim 2, wherein at least one of the heat sink elements is hollow.

8. The kit of parts according to claim 2, wherein at least one of the heat sink elements is a pin heat sink element.

9. The kit of parts according to claim 1, wherein at least one of the heat sink parts is hollow.

10. The kit of parts according to claim 1, wherein at least one of the heat sink parts is a rib heat sink element.

11. The kit of parts according to claim 10, wherein at least one of the heat sink parts has an undulating shape.

12. The kit of parts according to claim 1, wherein the heat sink parts extend substantially in parallel.

13. The kit of parts according to claim 1, further comprising a base arranged on ends of the heat sink parts.

14. The kit of parts according to claim 13, wherein the base is arranged opposite to the ends that serve as the contact areas.

15. The kit of parts according to claim 13, wherein the base is arranged to serve as a reservoir for receiving PCM material.

16. (canceled)

17. (canceled)

18. The kit of parts according to claim 1, wherein the guide structure is removable after the is mounted on the electronic device.

19. An electronic device provided with a and a guide structure according to claim 1.

20. The electronic device according to claim 19, which comprises a power switch.

21. A method of mounting a to a surface of an electronic device, comprising:
providing the heat sink assembly, the comprising a plurality of heat sink parts, each heat sink part having a contact area for contacting the surface of the electronic device, the heat sink parts being spaced apart and not directly connected to each other;
providing a guide structure to position the heat sink parts relative to the surface of the electronic device, the guide structure comprising respective openings for accepting and providing a sliding fit for the respective heat sink parts;
using the guide structure to position the heat sink parts of the on the surface of the electronic device.

22. The method according to claim 21, further comprising removing the guide structure once the heat sink structure is mounted on the electronic device.
